(19) United States
(12) Patent Application Publication
(10) Pub. No.: US 2003/0076713 A1
(43) Pub. Date: Apr. 24, 2003

(54) Storage medium for components

(76) Inventor: Keith E.G. Emery, San Diego, CA (US)

Correspondence Address: HEWLETT-PACKARD COMPANY, Intellectual Property Administration, P.O. Box 272400, Fort Collins, CO, 80527-2400, US

(21) Appl. No.: 10/046,450

(22) Filed: Oct. 19, 2001

(51) Int. Cl. G11C 7/00

(52) U.S. Cl. 365/200

(57) ABSTRACT

A replaceable component of an apparatus includes a storage medium, wherein the storage medium is at least one of readable and writeable.

### TECHNICAL FIELD

The subject matter disclosed herein relates to read/write storage mediums for a replaceable component of an apparatus.

### BACKGROUND

There is a desire for methods and devices that store information germane to the life-cycle of a component and for authenticating the component.

### BRIEF DESCRIPTION OF THE DRAWINGS

The present invention is illustrated by way of example and not limitation in the figures of the accompanying drawings. The same numbers are used throughout the figures to reference like components and/or features.

FIG. 1 illustrates an embodiment of a network environment in which multiple servers, workstations, and printers are coupled to one another via a data communication network.

FIG. 2 is a block diagram showing an embodiment of pertinent components of a printer suitable for use with various exemplary systems and/or methods described herein.

FIG. 3 is a block diagram showing an embodiment of pertinent components of a computer workstation suitable for use with various exemplary systems and/or methods described herein.

FIG. 4 illustrates an exemplary embodiment of life-cycle pathways for a component.

FIG. 5 illustrates an embodiment of a RAN device and a component having an exemplary storage medium attached thereto wherein the storage medium optionally includes a hologram.

FIG. 6 illustrates an embodiment of a system including a R/W device and a component having an exemplary storage medium attached thereto wherein the storage medium optionally includes a hologram.

FIG. 7 illustrates an embodiment of a manufacturer system including at least one R/W device and at least one component having an exemplary storage medium attached thereto wherein the storage medium optionally includes a hologram.

FIG. 8 illustrates an embodiment of a R/W head and a component having an exemplary storage medium attached thereto wherein the storage medium optionally includes a hologram.

FIG. 9 is an embodiment of a block diagram of an exemplary system including a storage medium, a R/W device and a computer.

FIG. 10 illustrates an exemplary embodiment of a printer including a R/W device and at least one component having an exemplary storage medium attached thereto wherein the storage medium optionally includes a hologram.

FIG. 11 is a block diagram of an exemplary embodiment of a method of reading data from and/or writing data to a storage medium attached to a printer cartridge component.

FIG. 12 is a block diagram of an exemplary embodiment of a life-cycle including exemplary methods of using a storage medium.

### DETAILED DESCRIPTION

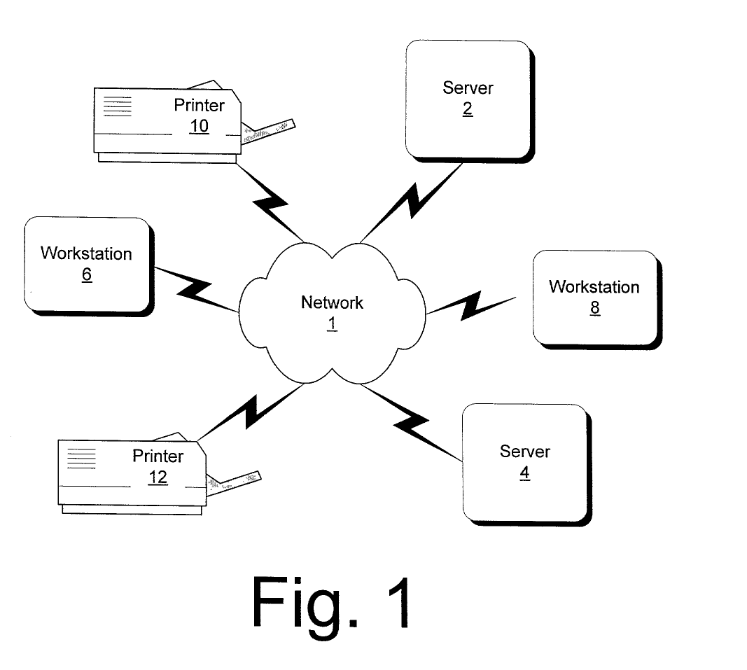

FIG. 1 illustrates an embodiment of a network environment in which multiple servers, workstations, and printers are coupled to one another via a data communication network 1. The network 1 couples together servers 2 and 4, computer workstations 6 and 8, and printers 10 and 12. Network 1 can be any type of network, such as a local area network (LAN) or a wide area network (WAN), using any type of network topology and any network communication protocol. In a particular embodiment, network 1 is the Internet. Although only a few devices are shown coupled to network 1, a typical network may include tens or hundreds of devices coupled to one another. Furthermore, network 1 may be coupled to one or more other networks, thereby providing coupling between a greater number of devices.

Servers 2 and 4 may be file servers, email servers, database servers, print servers, or any other type of network server. Workstations 6 and 8 can be any type of computing device, such as a personal computer. Particular embodiments of the invention illustrate printers 10 and 12 as laser printers. However, alternate embodiments of the invention are implemented with ink-jet, bubble-jet or any other type of printer. Furthermore, the teachings of the present invention may be applied to any type of printing device, such as copiers and fax machines. Although not shown in FIG. 1, one or more workstations and/or servers may contain a print rendering engine capable of converting raw print job information into a particular format (e.g., language) understood by certain types of printers. A printer menu editor application is optionally executed on workstation 6 or 8, or on server 2 or 4, to create or modify a printer menu structure. After the printer menu structure has been completed, the menu is “installed” by communicating the menu data across network 1 to one or more printers, such as printer 10 or 12.

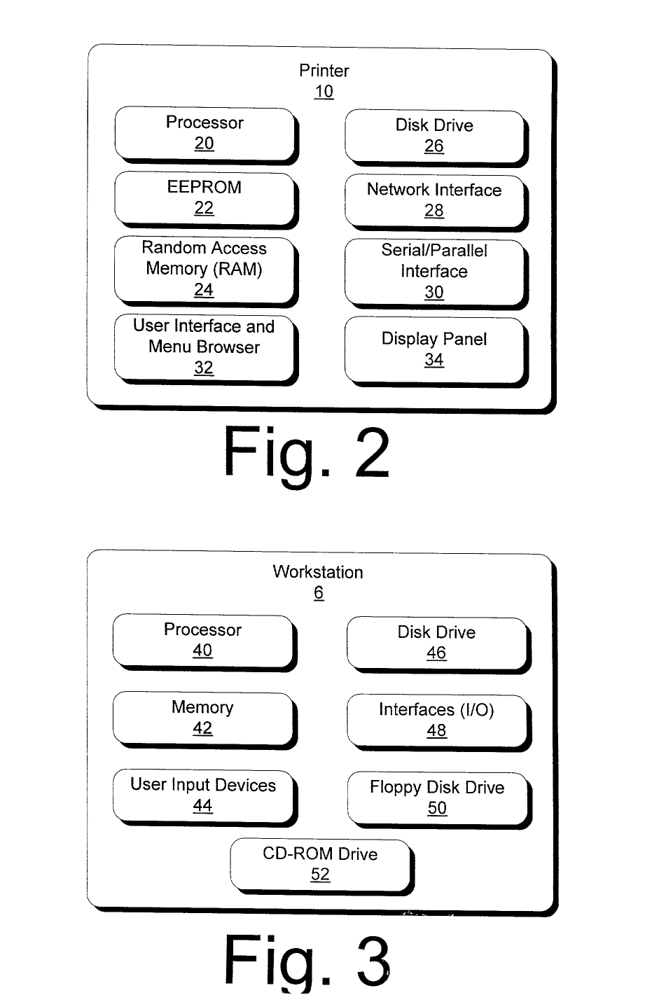

FIG. 2 is a block diagram showing an embodiment of pertinent components of printer 10 suitable for use with various examples presented herein. Printer 10 includes a processor 20, an electrically erasable programmable read-only memory (EEPROM) 22, and a random access memory (RAM) 24. Processor 20 processes various instructions necessary to operate the printer 10 and communicate with other devices. EEPROM 22 and RAM 24 store various information such as configuration information, fonts, templates, data being printed, and menu structure information. Although not shown in FIG. 2, a particular printer may also contain a ROM (non-erasable) in place of or in addition to EEPROM 22.

Printer 10 also includes a disk drive 26, a network interface 28, and a serial/parallel interface 30. Disk drive 26 provides additional storage for data being printed or other information used by the printer 10. Although both RAM 24 and disk drive 26 are illustrated in FIG. 2, a particular printer may contain either RAM 24 or disk drive 26, depending on the storage needs of the printer. For example, an inexpensive printer may contain a small amount of RAM 24 and no disk drive 26, thereby reducing the manufacturing cost of the printer. Network interface 28 provides a connection between printer 10 and a data communication network, such as network 1. Network interface 28 allows devices coupled to a common data communication network to send print jobs, menu data, and other information to printer 10 via the network. Similarly, serial/parallel interface 30 provides a data communication path directly between printer 10 and another device, such as a workstation, server, or other computing device. Although the printer 10 shown in FIG. 2 has two interfaces (network interface 28 and serial/parallel interface 30), a particular printer may only contain one interface.

As shown in FIG. 2, printer 10 also contains a user interface/menu browser 32 and a display panel 34. User interface 32 may be a series of buttons, switches or other indicators that are manipulated by the user of the printer. Display panel 34 is a graphical display that provides information regarding the status of the printer and the current options available through the menu structure. The printer 10 display panel 34 displays various menu options to the user of the printer. The display panel and associated control buttons allow the user of the printer to navigate the printer's menu structure.

FIG. 3 is a block diagram showing an embodiment of pertinent components of a computer workstation 6 in accordance with the invention. Workstation 6 includes a processor 40, a memory 42 (such as ROM and RAM), user input devices 44, a disk drive 46, interfaces 48 for inputting and outputting data, a floppy disk drive 50, and a CD-ROM drive 52. Processor 40 performs various instructions to control the operation of workstation 6. Memory 42, disk drive 46, and floppy disk drive 50, and CD-ROM drive 52 provide data storage mechanisms. User input devices 44 include a keyboard, mouse, pointing device, or other mechanism for inputting information to workstation 6. Interfaces 48 provide a mechanism for workstation 6 to communicate with other devices.

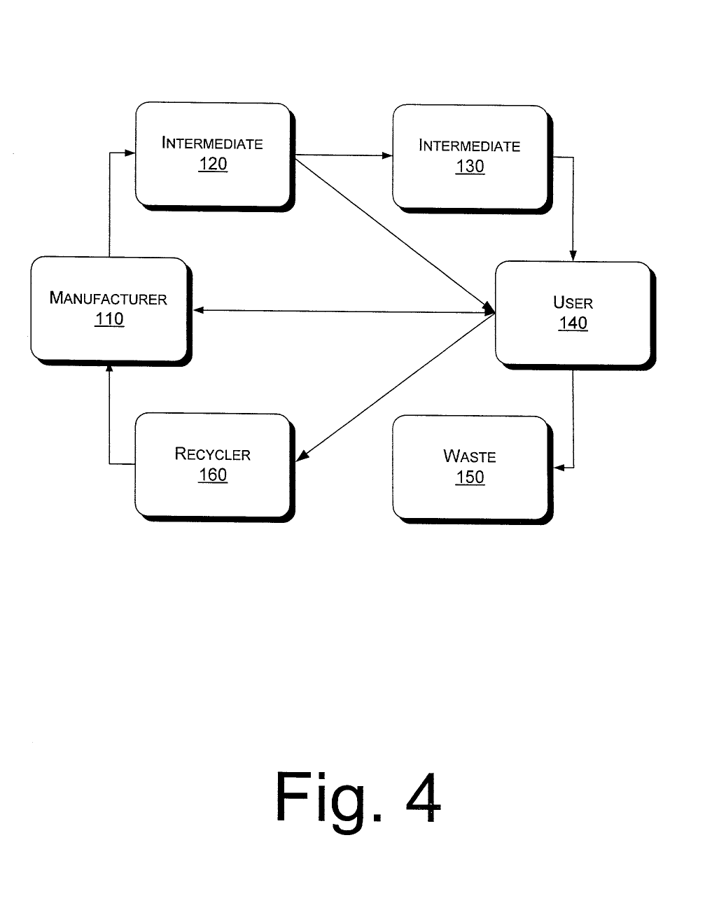

FIG. 4 shows a block diagram that illustrates an embodiment of a life cycle for a manufactured component. The component's life cycle begins at a manufacturer 110. From the manufacturer 110, the component proceeds to at least one intermediate 120,130 or directly to a user 140. After the user 140, the component proceeds to either a recycler 160 or to a waste handler 150. As shown, the recycler 160 returns the component to the manufacturer 110; however, a recycler 160 may also send a component to an intermediate (e.g., 120, 130) or to a user 140.

Throughout the component's life cycle, the component is exposed to various conditions, which include manufacturing, shipping, storage and operating conditions. As a result of this exposure, the component may wear, discharge material, discharge energy, etc. The value of the component may also increase and/or decrease over time. At some point in time, the component may ultimately deplete its usefulness.

Often proof of authenticity is a concern during a component's life cycle. For example, an intermediate 120, 130, a user 140, a waste handler 150, or a recycler 160 may require proof of authenticity.

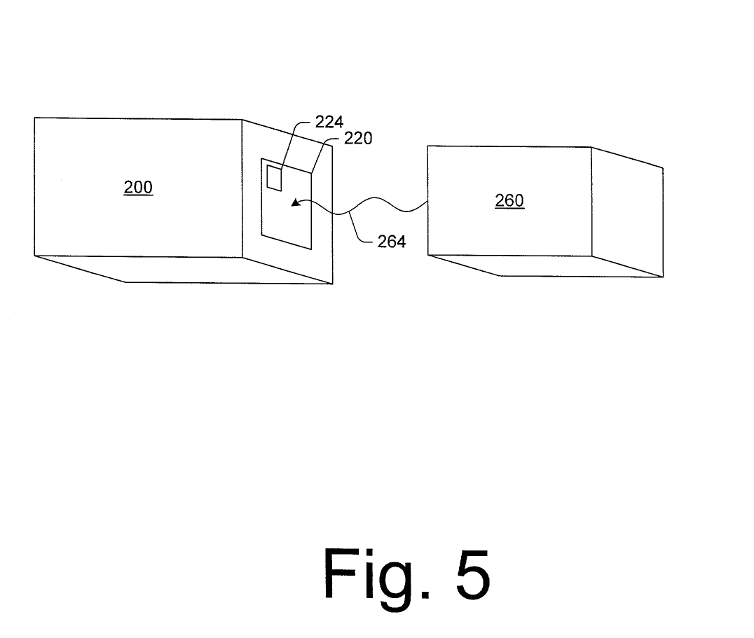

FIG. 5 shows a diagram that illustrates an embodiment of a component 200 having an attached data storage medium 220. The exemplary data storage medium 220 further includes an authenticity hologram 224. FIG. 5 also shows a read and/or write device 260 (abbreviated herein as Read/Write device or R/W device) for reading and/or writing data to the storage medium 220. Reading and/or writing occur through wireless electromagnetic (EM) transmission 264, such as, but not limited to, EM transmission having IR, UV, and/or visible wavelengths. The spacing between the storage medium 220 and the RAN device 260 is for purposes of illustration, actual spacing depends on characteristics of the storage medium 220 and/or R/W device 260. For example, in an exemplary arrangement, the spacing may approximate that typically found between a CD and a read and/or write head.

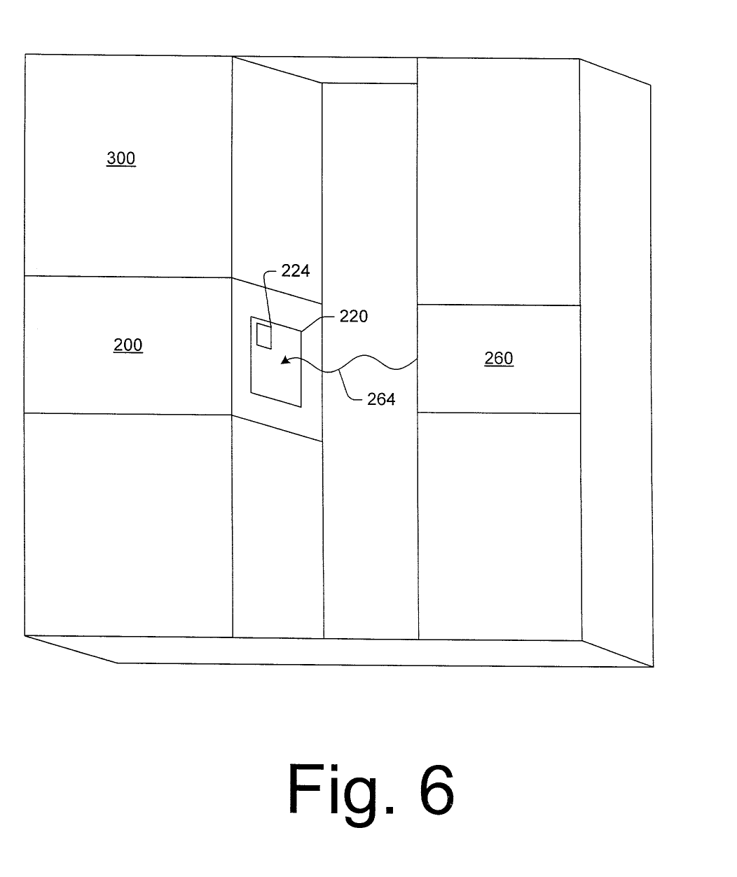

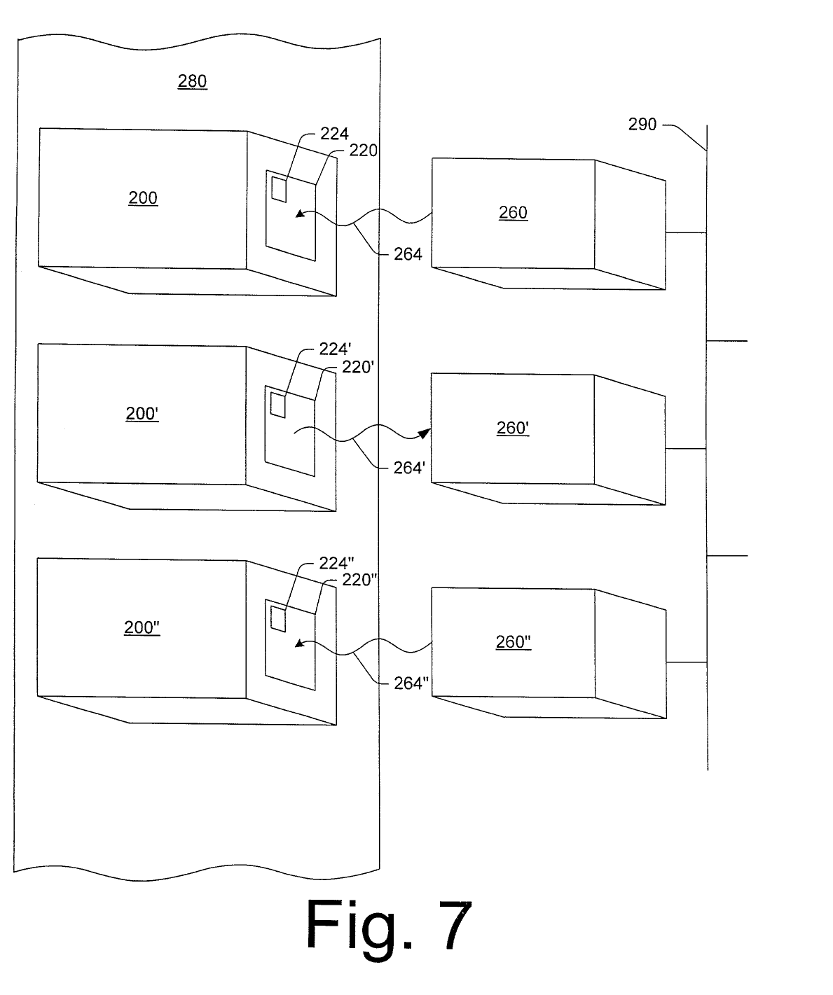

FIG. 6 shows a diagram that illustrates an embodiment of a component in an assembly 300 wherein the assembly comprises a R/W device 260. In this exemplary assembly 300, the R/W device 260 reads and/or writes data to the storage medium 220 through EM transmission 264. Further, the hologram 224 is optionally readily visible upon inspection of the component 200 in the assembly 300. The spacing between the storage medium 220 and the R/W device 260 is for purposes of illustration, actual spacing depends on characteristics of the assembly 300, storage medium 220 and/or R/W device 260. For example, in one exemplary assembly, the spacing may approximate that typically found between a CD and a read and/or write head.

FIG. 7 shows a diagram that illustrates an embodiment of a plurality of components 200, 200′, 200″ and a plurality of R/W devices 260, 260′, 260″. A surface 280 supports the components 200, 200′, 200″ and a communication bus connects the R/W devices 260, 260′, 260″ to a network. The surface 280 optionally comprises a conveyor belt, a manufacturing table or the like. As shown, two of the R/W devices 260, 260″ transmit EM energy 264, 264″ toward the storage medium 220 whereas one of the R/W devices 260′ receives reflected EM energy 264′. In general, each R/W device can transmit and receive EM. In one exemplary system, a R/W device provides an angled EM beam and allows for recognition of a line or lines on the storage medium, which are optionally used for tracking. Of course, other geometric beam/storage medium arrangements are also possible. In addition, according to various exemplary methods and/or exemplary devices disclosed herein, information is written to and/or read from a storage medium attached to a component without contact between a R/W device and the storage medium, for example, as described herein, use of an EM beam does not involve contact between a R/W device and a storage medium.

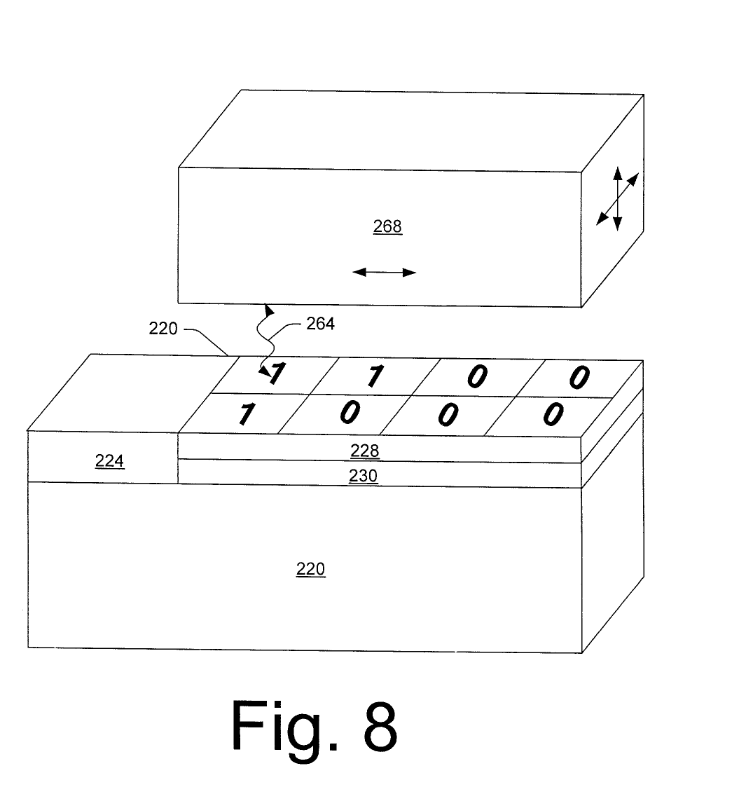

FIG. 8 shows a diagram that illustrates an embodiment of a storage medium 220 attached to a component 200. The storage medium 220 further comprises a hologram 224, a read and/or write storage medium 228 and a base storage medium 230. As shown in FIG. 8, the storage medium 220 has eight bits of data, represented as zeros (0) and ones (1), in two four bit rows. The data area is optionally referred to herein as a data cell. FIG. 8 also shows a R/W head 268 positioned above the storage medium 220 and capable of transmitting and receiving EM energy 264. Arrows on front and side surfaces of the R/W head 268 indicate three-dimensional positioning capabilities.

An exemplary storage medium 220 includes a read and/or write storage medium 228 and a base storage medium 230. This exemplary storage medium 220 further includes reflective properties and/or a reflective metal layer, which are optionally part of the read and/or write storage medium 228 and/or base storage medium 230. The read and/or write storage medium 228 optionally includes an organic material, e.g., an organic dye. For example, an exemplary storage medium 220 optionally includes a blue-green polymer dye backed by a reflective gold coating. To simplify head 268 positioning, a track is optionally present on a blank storage medium 220 or created during and/or before a write procedure. In general, a laser beam can follow such a track during both data reading and writing.

During a write procedure, data marks, or “pits”, are formed inside the light-absorbing organic film. In an exemplary storage medium 228, the thermal conductivity of the organic material is very low (much lower than that of metals). R/W head 268 energy 264 absorbed by such an organic material dissipates in the form of heat, causing local material ablation and pit formation. In general, pits scatter energy 264 whereas “lands” (areas having reflective properties) exhibit minimal scattering and primarily reflect energy back to the R/W head 268.

According to the exemplary storage medium 220 and R/W head 268 shown in FIG. 8, one of the rows of data contains data useful for positioning the R/W head 268 and/or for other R/W control. For example, the row containing “1000” may optionally serve as a locator track for the R/W head 268 such that it can read an adjacent row of data. Alternatively, if required, the storage medium 220 comprises a track that does not contain bit information. For example, a track having a depth of approximately one-eighth the wavelength of incident energy is commonly used in compact disc technology to guide a R/W head. A R/W head 268 optionally imparts such a track and/or positioning data during a component manufacturing process wherein the storage medium 220 is already attached to the component. A storage medium may also include a read and/or a write test area.

The hologram 224 comprises a hologram type such as, but not limited to, an embossed narrow web film; an embossed hot-stamping foil; an embossed metallized paper; an embossed stripe; an embossed thread; a demetallized or part-demetallized embossed foil; a HRI coated film; and/or a photopolymer. The hologram 224 comprises an image style such as, but not limited to, a uniform repeating pattern; a 2D/3D; a dot matrix; a diffraction grating; a 3D; a multi-channel; a stereogram; a covert image; and/or combination thereof. Viewing of the hologram 224 is achieved through use of a source, such as, but not limited to, an ambient source; a point source; a laser; and/or an LED. The exemplary hologram 224 optionally includes a company's logo, trademarks, and/or other identifying information.

The storage medium 220 optionally comprises an adhesive for attachment to a component. Such adhesives include those commonly used for decals. Alternatively, or in addition to, the storage medium attaches to a component through mechanical means, such as, but not limited to, snap fit means including prongs or the like. In yet another alternative, a component includes an integral storage medium.

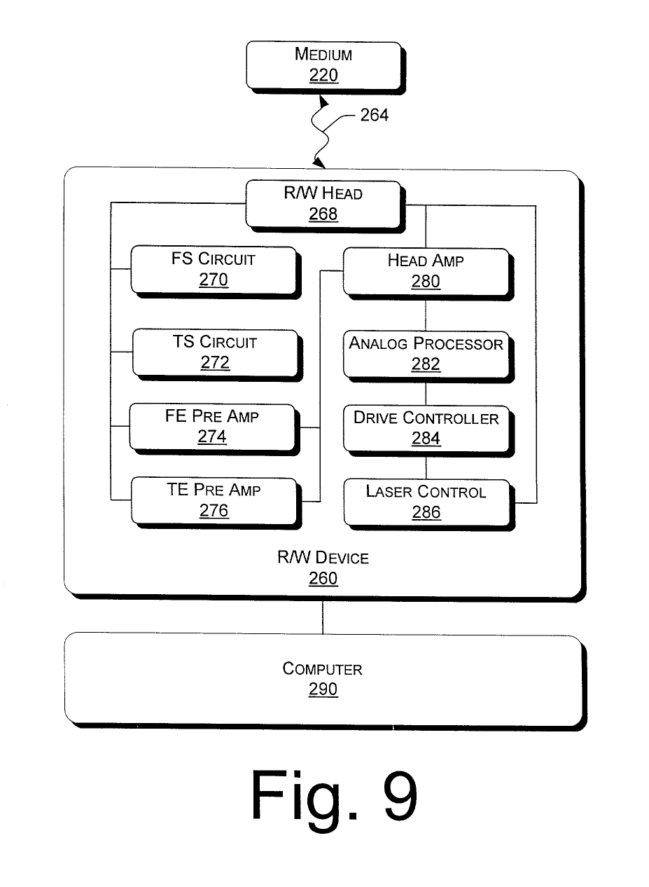

FIG. 9 shows a block diagram that illustrates an embodiment of a system that includes a storage medium 220, a R/W device 260, and a computer 290. In this system, the computer 290 controls the R/W device 260 to either write or read data from the storage medium 220. Communication between the R/W device 260 and the computer 290 occurs through any of a variety of interfaces known in the art, including, wireless, ATAPI, etc. To read and/or write data, R/W device 260 includes a R/W head 268 that can emit and/or receive EM energy and associated circuitry and/or software.

In one exemplary system, the R/W head 268 includes a photodiode, a laser, a lens, equipment to direct a laser beam through the lens and/or to position a laser beam. The equipment optionally includes a cradle that holds and allows for positioning of the laser and/or optical elements. During a read process, the R/W head 268 directs energy 264 emitted from the laser to the storage medium 220. The incident energy 264 impacts the storage medium 220 on a “pit” or on a “land”. A pit primarily scatters the incident energy 264 whereas a land primarily reflects the incident energy 264 back to the R/W head 268. A photodiode in the R/W head 268 detects the reflected energy 264. The R/W device 260 and/or the computer 290 then determine whether the beam detected a track and/or a bit of information. To account for dust, scratches, etc., the R/W device 260 optionally uses error correction logic to aid in this determination. The exemplary system further optionally includes a R/W device 260 that can detect a hologram on the storage medium 220.

Referring to FIG. 9, a read process optionally includes use of a head amplifier 280, a focus error preamplifier 274, a tracking error amplifier 276, a focus servo circuit 270 and a tracking servo circuit 272. For example, reflected energy 264 impacts a detector (e.g., a photodiode), which produces a signal. A head amplifier 280 amplifies this signal and distinguishes data, tracking and/or focus signal components. An analog processor 282 receives the data signal and converts the signal to a binary value; a tracking error preamplifier 276 receives the tracking signal, amplifies the tracking signal and feeds it to a tracking servo circuit 272; and a focus error preamplifier 274 receives the focus signal, amplifies the focus signal and feeds it to a focus servo circuit 270. The controller 284 receives the binary value from the analog processor 282, which is subsequently available for communication to the computer 290. The tracking servo circuit 272 produces a signal, which the circuit sends to a tracking actuator in, for example, the R/W head 268 to maintain proper tracking of the laser energy 264 with respect to the storage medium 220. The focus servo circuit 270 produces a signal, which the circuit sends to a focus actuator in, for example, the R/W head 268 to maintain proper focus of the laser energy 264 with respect to the storage medium 220.

The exemplary system shown in FIG. 9 also optionally provides for a write process. For example, a user and/or a computer 290 prepare data for writing to the storage medium 220. The computer 290 sends the data to a controller 284 resident on the R/W device 260. The controller 284 prepares the data for subsequent communication to a laser control circuit 286, which converts the data into a signal for optical modulation of a laser (e.g., a laser diode). Energy 264 emitted from the modulated laser impacts a writeable storage medium (e.g., 220) to record the data.

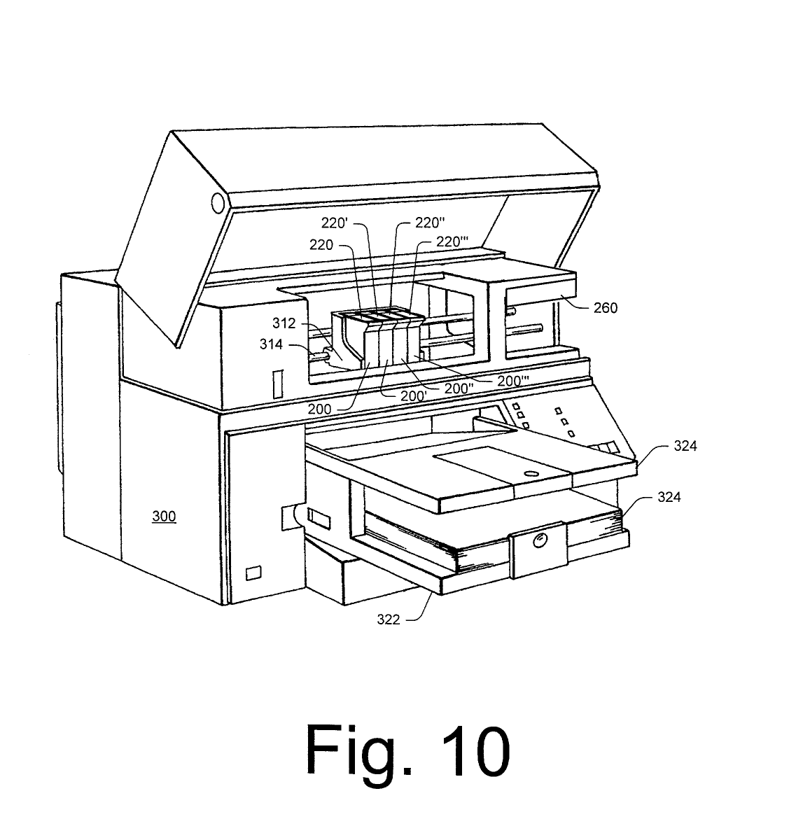

FIG. 10 shows an embodiment of exemplary printer 300 including components 200, 200′, 200″, 200′″ having storage media 220, 220′, 220″, 220′″ attached thereto and a R/W device 260. This exemplary printer 300 optionally includes the features of the printers described in FIGS. 1 and 2. In FIG. 10, the exemplary printer 300 includes a movable carriage 312 supported on a rail 314. Movable carriage 312 includes a plurality of components 200, 200′, 200″, 200′″, such as, printer ink cartridges. Printer 300 also is provided with input tray 322 containing a number of sheets of paper or other suitable ink-receiving storage medium 324, and a tipper output tray 326 for receiving the printed media.

In this exemplary printer 300, the movable carriage 316 can position the components 200, 200′, 200″, 200′″ in relation to the R/W device 260 to allow for reading and/or writing of data (and/or track information) to each component's respective storage medium 200, 200′, 200″, 200′″. A computer or processor (e.g., such as computer 290 of FIG. 9) is optionally included in the exemplary printer 300 and in communication with the R/W device 260, directly and/or indirectly.

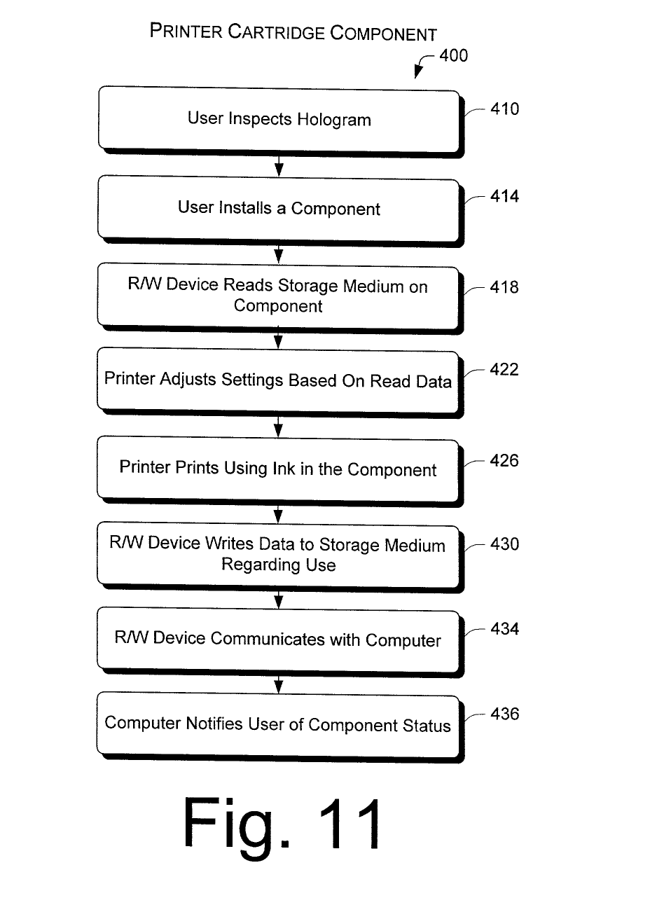

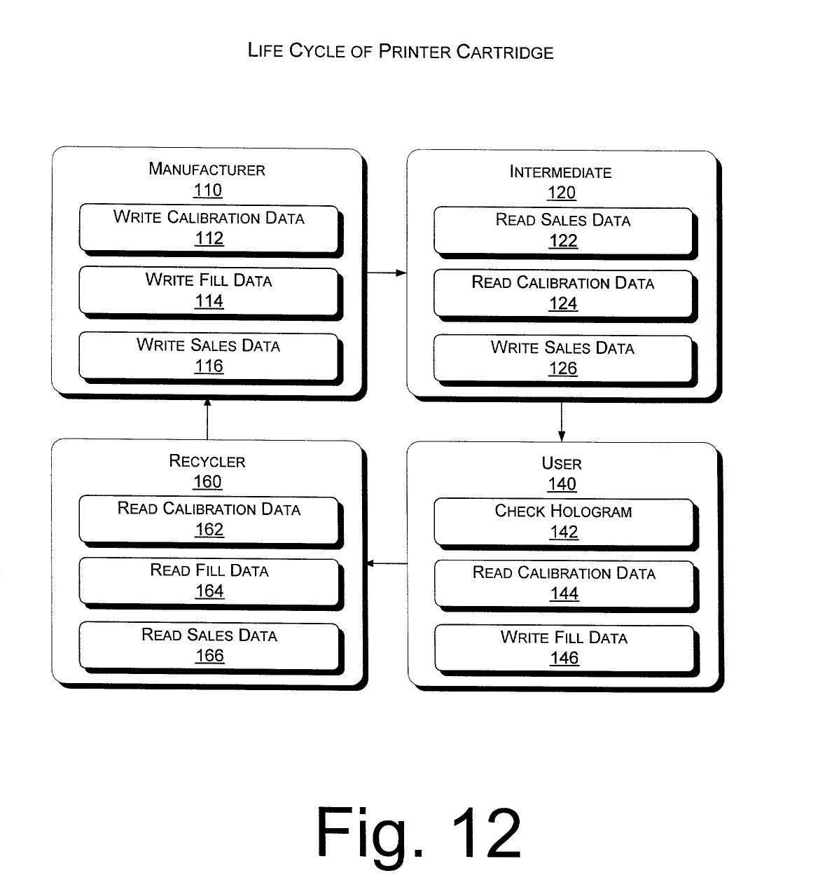

In the flow diagrams of FIGS. 11 and 12 various embodiments of algorithmic acts are summarized in individual “blocks”. Such blocks describe specific actions or decisions that are made or carried out as the method or process proceeds. Where a processor is employed, the flow charts presented herein provide a basis for a “control program” or software/firmware that may be used by such a processor (or equivalent) to effectuate the desired method. As such, the methods or processes are implementable as machine-readable instructions stored in memory that, when executed by a processor, perform the various acts illustrated as blocks. Those skilled in the art may readily write such a control program based on the flow charts and other descriptions presented herein. Software to program the processors and, additionally, any and all computer-readable media on which such software might be embodied are within the scope of this disclosure. Examples of such computer-readable media include, without limitation, floppy disks, hard disks, CDs, RAM, ROM, flash memory and the like. In an exemplary system, a storage medium, such as that described above, includes software.

Referring to FIG. 11, a block diagram of an exemplary method 400 of using a storage medium attached to a printer cartridge component is shown. In a hologram check block 410, a user inspects a hologram on the storage medium to authenticate the source of the printer cartridge. Next, in an installation block 414, a user installs the component. Once installed, a read block 418 reads the storage medium, using, for example, a R/W device such as that described above. The read block 418 reads data, which optionally pertains to printer settings associated with the component. In an adjustment block 422, a computer and/or a processor in the printer adjust printer settings based on the data read in the read block 418.

Once adjusted, if required, a print block 426 instructs the printer to print using ink contained in the component. Subsequent to the print block 426, a write block 428 writes data to the storage medium regarding the print procedure, e.g., how much ink was discharged, etc. Subsequently, in a communication block 432, the R/W Device communicates directly and/or indirectly with a computer that is in communication with the printer. In a notification block 436, the computer notifies the user of the status of the component.

In yet another exemplary printer system, a print cartridge includes a R/W medium containing information related to the cartridge. For example, the information optionally indicates whether the cartridge is new, previously used and refilled, or an unknown cartridge type. The information optionally includes a characteristic (or characteristics) of the component, for example, but not limited to, age, use, prior use, compatibility, manufacturer, and/or ink level. A user interface, on the printer or associated with the printer, may relay such information to a user. The printer system and/or user may respond to such information and/or override or ignore such information and thereby, for example, enable printing with the print cartridge in response to print commands. Alternatively, a user and/or system may need to satisfy certain predetermined conditions prior to printing with the cartridge. In general, a system may respond to information stored on a R/W medium automatically and/or through user control.

While the exemplary method described above with reference to FIG. 11 includes a printer and a printer cartridge component, a similar exemplary method applies to other components. For example, another exemplary system includes a computer hard drive having a storage medium attached thereto and a computer having a R/W device such as that described above installed therein. In such a system, the R/W device reads and/or writes data to the storage medium regarding the status of the computer hard drive.

In yet another exemplary system, R/W media appear on at least one component of a system. For example, a printer system may include a battery, a tray, a printer housing and/or other components having a R/W medium attached thereto. In yet another example, a component includes a R/W medium and a R/W device. In such an example, information from the R/W device controls the component without input from other parts of an assembly or system and/or controls the component via communication with other parts of an assembly or system.

As discussed herein, the R/W medium optionally includes a hologram. The hologram optionally comprises a R/W medium for storing information. Processes for reading information from a holographic medium is known in the art as are processes for writing information to a medium in holographic form. In such an example, the R/W medium optionally comprises a holographic R/W area without an additional non-holographic R/W area. Alternatively, a R/W medium includes both a R/W holographic area and a non-holographic R/W area.

A block diagram of a printer cartridge life-cycle is shown in FIG. 12 and described with reference to FIG. 4. As shown in FIG. 12, the life cycle includes a manufacturer 110, an intermediate 120, a user 140 and a recycler 160. At the manufacturer 110, an exemplary method includes a write calibration data block 112, a write fill data block and a write sales data block 116. At the intermediate 120, an exemplary method includes a read sales data block 122, a read calibration data block 124 and a write sales data block 126. At the user 140, an exemplary method includes a check hologram block 142, a read calibration data block 144 and a write fill data block 146. At a recycler 160, an exemplary method includes a read calibration data block 162, a read fill data block and a read sales data block 166.

While the exemplary methods described above with reference to FIG. 12 include a printer cartridge component, a similar exemplary method applies to other components. For example, another exemplary system includes a computer hard drive having a storage medium attached thereto, optionally attached to an external surface of the computer hard drive. In such a system, a R/W device at the manufacturer 110, the intermediate 120, the user 140 and/or the recycler 160 reads and/or writes data to the storage medium regarding the status of the computer hard drive. Any replaceable component in a printer or image forming device can have the storage medium of the present inventions attached thereto. Alternatively or additionally, the printer or image forming device has a storage device being at least one of readable and writeable.

Although the invention has been described in language specific to structural features and/or methodological steps, it is to be understood that the invention defined in the appended claims is not necessarily limited to the specific features or steps described. Rather, the specific features and blocks are disclosed as preferred forms of implementing the claimed invention.

What is Claimed is:

1. A storage medium attachable to a replaceable component of an apparatus, the storage medium comprising a hologram.

2. The storage medium of claim 1 wherein the storage medium further comprises a laser writeable storage medium.

3. The storage medium of claim 1 wherein the hologram includes a company logo.

4. The storage medium of claim 1 wherein the storage medium comprises an adhesive for attachment to the component.

5. The storage medium of claim 1 wherein the storage medium snap-fits to the component.

6. The storage medium of claim 1 wherein the storage medium is readable.

7. The storage medium of claim I wherein the storage medium is writeable.

8. A print cartridge comprising a storage medium.

9. The cartridge of claim 8 wherein the storage medium comprises a hologram.

10. The cartridge of claim 8 wherein the storage medium comprises indicia of authenticity.

11. The cartridge of claim 8 wherein the storage medium comprises a laser writeable storage medium.

12. The cartridge of claim 8 wherein the cartridge comprises an ink jet printer cartridge.

13. A system comprising a R/W device and a component, wherein the component includes a R/W storage medium that interfaces with the R/W device.

14. The system of claim 13 wherein the storage medium includes at least one of a hologram and a laser writeable storage medium.

15. The system of claim 13 wherein the system further comprises a manufacturing line, the manufacturing line including the R/W device.

16. The system of claim 13 wherein the component includes a printer cartridge.

17. The system of claim 13 wherein the system further comprises an image forming device, the image forming device configured to receive the component and including the R/W device.

18. A method of reading data from a storage medium attached to a component, the method comprising:
emitting energy from a device positioned in proximity to the storage medium, wherein the device is at least one of readable and writeable;
detecting energy reflected from the storage medium; and
determining a bit value based on the detected energy.

19. The method of claim 18 wherein the component is a printer cartridge.

20. The method of claim 18 wherein the device is housed in a printer.

21. The method of claim 20 wherein the component is installed in the printer.

22. The method of claim 18 wherein the emitting comprises laser emission.

23. A method of writing data to a storage medium attached to a component comprising:
instructing a device, wherein the device is at least one of readable and writeable; and
emitting energy from the device, the emitting based on the instructing and the device positioned in proximity to the storage medium.

24. The method of claim 23 wherein the device is housed in a printer.

25. The method of claim 23 wherein the component includes a printer cartridge.

26. The method of claim 23 wherein the emitting includes laser emission.

27. A printer comprising components, at least one of the components having a laser storage medium attached thereto, wherein the storage medium is at least one of readable and writeable.

28. A method of instructing an image forming device comprising:
installing a component in the image forming device, the component having a storage medium attached thereto, the storage medium comprising stored information;
reading the stored information; and
instructing the image forming device based on the stored information.

29. The method of claim 28 wherein the component includes a printer cartridge.

30. The method of claim 28 wherein the stored information indicates a characteristic of the component.

31. The method of claim 30 wherein the characteristic includes a characteristic selected from at least one of age, use, prior use, compatibility, manufacturer, and fluid level of the component.
